(19) United States
(12) Patent Application Publication
(10) Pub. No.: US 2007/0235862 A1
(43) Pub. Date: Oct. 11, 2007

(54) Hybrid flip-chip and wire-bond connection package system

(75) Inventors: Shih-Cheng Chang, Hsin-Chu City (TW); Jack Hu, Pingzhen City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 11/393,301

(22) Filed: Mar. 29, 2006

(51) Int. Cl. H01L 23/34

(52) U.S. Cl. 257/723

(57) ABSTRACT

A hybrid flip chip and wire bond semiconductor connection package for an integrated circuit. The hybrid package includes a package substrate, a plurality of flip chip pads, and a plurality of wire-bond pads. The package substrate has at least one void or opening with a top side and a bottom side. The flip chip pads mounted on the top side of the package substrate, while the wire-bond pads mounted on the bottom side of the package substrate. The wire-bond pads are configured to receive the integrated circuit.

### BACKGROUND

1. Field of the Invention

Aspects of the present invention relate in general to semiconductor packaging. In particular, aspects include a space-saving integrated circuit package that employs both wire-bond and flip-chip connections.

2. Description of the Related Art

In the field of packaging integrated circuits, there are competing goals. Besides smaller packaging size, integrated circuit packaging requires numerous signal inputs and outputs, as well as power/ground connections.

The cross-section of a traditional wire-bond package 1000 is depicted in FIG. 1. The integrated circuit substrate 1002 is connected to contacts 1004 made through conductive bonding members, which are in turn, connected to the packaging substrate 1006. Finally, the packaging substrate 1006 communicates to the outside world via a ball grid array 1008.

In contrast, FIG. 2 illustrates a cross-section of a conventional wire bond package 2000. In a wire bond package 2000, the integrated circuit substrate 2002 has contacting contact pads 2010 which are connected, via wire 2012, to contact pads 2014 on the packaging substrate 2006. The packaging substrate communicates to the outside world via a ball grid array 2008.

### SUMMARY

Embodiments of the present invention include a semiconductor connection package for an integrated circuit with a package substrate, a plurality of flip hip pads, and a plurality of wire-bond pads. The package substrate has at least one void or opening with a top side and a bottom side. The flip chip pads mounted on the top side of the package substrate, while the wire-bond pads mounted on the bottom side of the package substrate. The wire-bond pads are configured to receive the integrated circuit.

### BRIEF DESCRIPTION OF THE DRAWINGS

FIG. 1 depicts a flip chip package connection of the PRIOR ART.

FIG. 2 illustrates a wire bond package connection of the PRIOR ART.

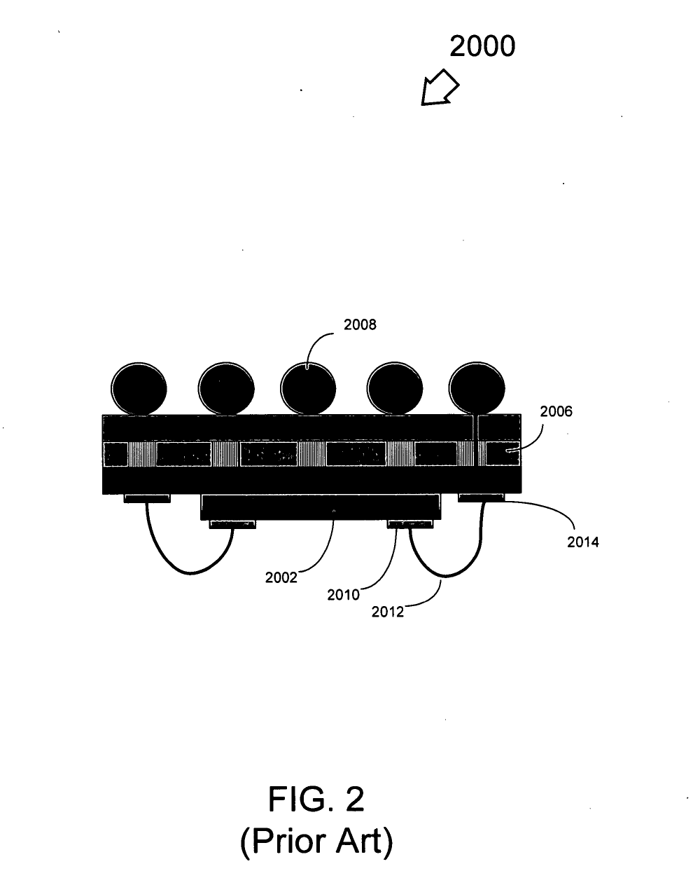

FIG. 3 depicts a cross-section view of a hybrid flip chip and wire bond embodiment, configured to provide a greater number of power/ground pads and signal input/output pads on a single package.

FIG. 4 is a top view of a hybrid flip chip and wire bond embodiment, configured to provide a greater number of power/ground pads and signal input/output pads on a single package.

FIG. 5 illustrates a top view of a multiple integrated circuit hybrid flip chip and wire bond embodiment, configured with multiple voids to provide a greater number of power/ground pads and signal input/output pads on a single package.

FIG. 6 is a cross-section view showing a single integrated-circuit hybrid flip chip and wire bond embodiment, configured with multiple voids to provide a greater number of power/ground pads and signal input/output pads on a single package.

FIG. 7 is a cross-section view showing a multiple integrated-circuit hybrid flip chip and wire bond embodiment, configured with multiple voids to provide a greater number of power/ground pads and signal input/output pads on a single package.

FIG. 8 is a flow chart detailing the manufacturing of an integrated-circuit hybrid flip chip and wire bond embodiment, configured with multiple voids to provide a greater number of power/ground pads and signal input/output pads on a single package.

### DETAILED DESCRIPTION

One aspect of the present invention includes the realization that a traditional wire-bond package does not enable as many power/ground current connection pads as flip-chip packages, while traditional flip-chip package does not enable as many connections or fan out signal input/outputs within minimum substrate layer numbers as wire-bond packages. What is needed is a hybrid flip chip and wire bond connection, configured to provide a greater number of power/ground pads and signal input/output pads on a single package

Embodiments of the present invention include a hybrid flip-chip and wire bond semiconductor connection package for an integrated circuit and process embodiments.

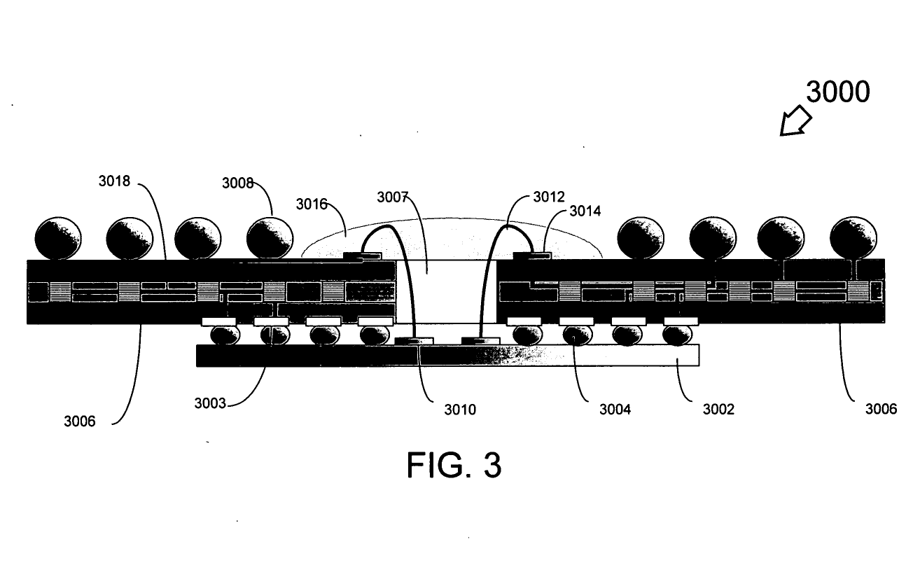

Operation of embodiments of the present invention may be illustrated by example. FIG. 3 depicts a cross-section of a hybrid flip chip and wire bond embodiment 3000, configured to provide a greater number of power/ground pads and signal input/output pads on a single package, constructed and operative in accordance with an embodiment of the present invention. In such an embodiment, an integrated circuit (IC) will enable connections via wire bonds and as a flip chip. A void or opening in the packaging substrate facilitates wire bond connections, while metal contacts allow the integrated circuit to be mounted as a flip chip.

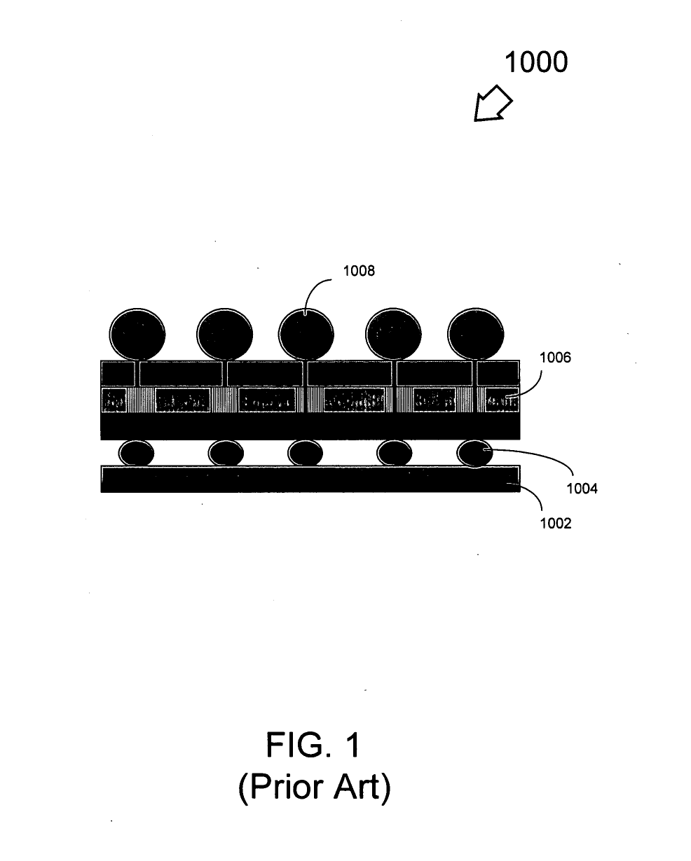

The integrated circuit 3002 is designed with wire-bond pads 3010 and flip-chip pads on the surface. Contacts 3004, made through conductive bonding members, are placed on the flip-chip pads 3003, and connected to the package substrate material 3006 as a flip chip. Contacts 3004 may be any accomplished by any method known in the art. As illustrated in FIG. 1, “C4” solder balls may be used as contacts 3004, connecting counter part pads on both the integrated circuit 3002 and the package substrate 3006; use of solder balls carry signals, power, also provide mechanical attachment. Package substrate 3006 may be any integrated circuit packaging known in the art with at least one cavity, hole or void that extends through the package substrate 3006. The void 3007 in the package substrate 3006 allows the wire-bond connectivity from the surface of the integrated circuit 3002 to the other side of the package substrate 3006 through the void 3007. As will be discussed below in other embodiments, a package substrate 3006 may have more than one void 3007. Wires 3012 connect from the integrated circuit wire-bond pads 3010 to wire-bond pads 3014 on the package substrate 3006. It is understood, by those knowledgeable in the art, the package substrate 3006 provides various signal paths 3018 from the wire-bond paths 3014 and contacts 3004 to additional ball grid array (BGA) contacts 3008. The ball grid array contacts 3008 are configured to convey input/output signals from the package substrate to electrical contacts external to the integrated circuit. The integrated circuit 3002, connection pads 3010 3014, and wires 3012 may be encapsulated by an electrically non-conductive material, such as epoxy 3016 or other material known in the art. It is understood that epoxy 3016 may be replace interchangeably with other encapsulation materials, including epoxy resin molding compound, polyimide adhesive, or other materials as is known in the art. Encapsulation prevents potential damage from moisture or other contaminants through the contact.

The package substrate 3006 may comprise polyimide tape, FR-4, organic build-up, ceramic substrate, or any other material known in the art. The contacts 3008 may be made of eutectic/high lead/lead free solder balls, NiAu alloys/eutectic/high lead/lead free solder C4 bumps, or other material known in the art. Wire bonds may be made of gold or other conductive material known in the art. Materials for wire bond pads include Au plated wire-bond pads, Cu/Al/NiAu pads or other conductive materials known in the art.

As illustrated and obvious to one of ordinary skill in the art, there may be a plurality of integrated circuit contacts 3004, ball grid array contacts 3008, integrated circuit wire bond pads 3010, wires 3012, and packaging substrate wire bond pads 3014. The number of such elements may depend upon the integrated circuit 3002 and the packaging requirements.

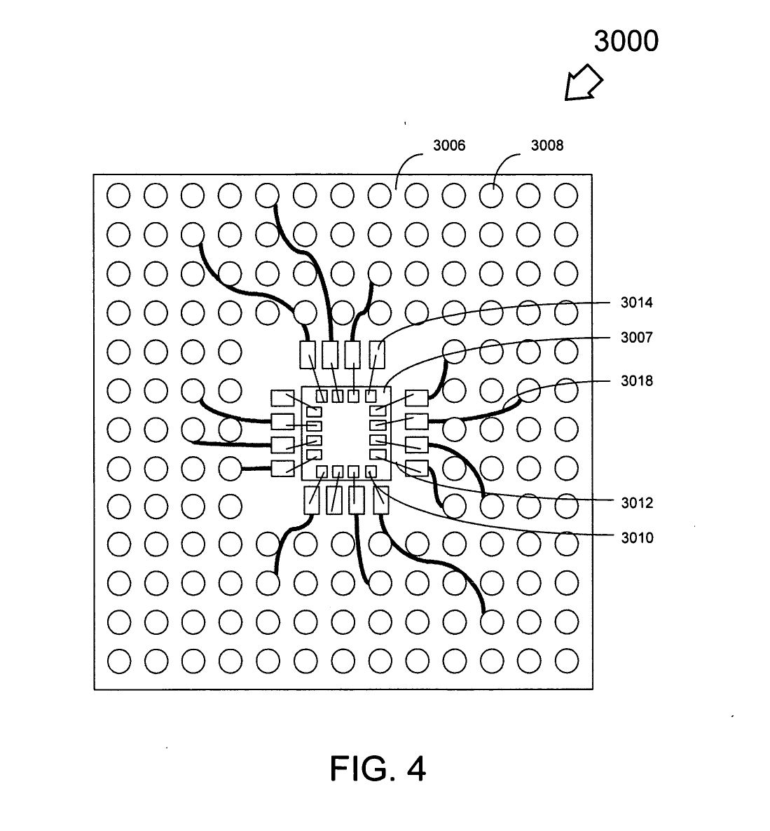

Moving on, FIG. 4 shows a top-view of the hybrid flip chip and wire bond embodiment 3000 from FIG. 3, configured to provide a greater number of power/ground pads and signal input/output pads on a single package, constructed and operative in accordance with an embodiment of the present invention. From the top, the ball grid array contacts 3008 are visible on top of the package substrate 3006. As discussed earlier, the package substrate 3006 is formed such there is a void 3007 through substrate 3006, that allows access to the integrated circuit below. The void 3007 facilitates the wire-bond 3012 connectivity from the surface of the integrated circuit wire bond pad 3010 to the package substrate wire bond pad 3014. The various signal paths 3018 may link wire bond pads 3014 to ball grid array contacts 3008.

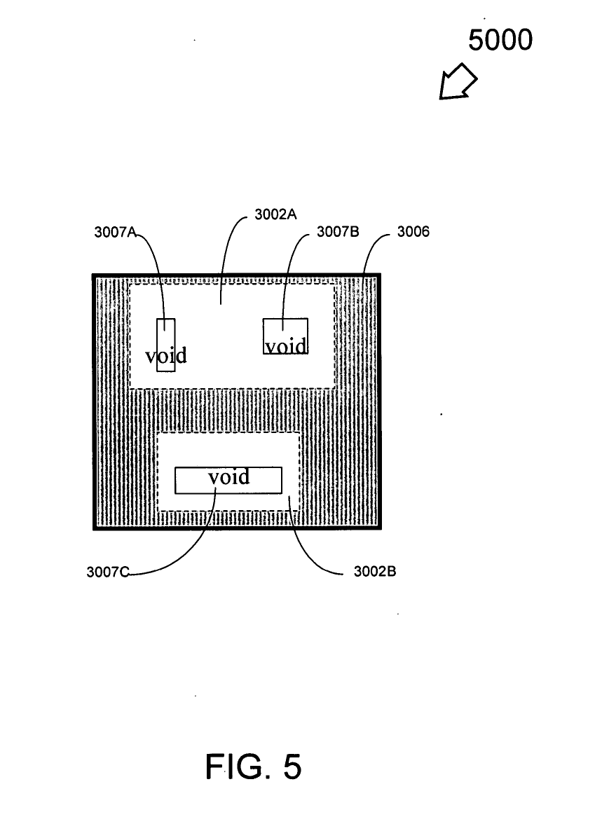

Hybrid flip chip and wire bond embodiments may be expanded to have multiple voids in a substrate to accommodate greater integrated circuit connectivity, and/or group multiple integrated circuits in a single package. FIGS. 5-7 depict such examples, constructed and operative in accordance with embodiments of the present invention. Note that corresponding elements within FIGS. 5-7 are numbered identically to the elements of FIG. 3.

FIG. 5 illustrates a top view of a multiple integrated circuit hybrid flip chip and wire bond embodiment, configured to provide a greater number of power/ground pads and signal input/output pads on a single package. In such an embodiment, multiple integrated circuits 3002A-B may be combined under a single package substrate 3006. Although two integrated circuits 3002A-B are depicted, it is understood that any number of integrated circuits 3002 may be used, depending upon the application. To facilitate wire-bond connections between the integrated circuits and the package substrate, multiple voids 3007A-C are drilled, formed, or otherwise prepared in the package substrate 3006. Note that voids do not necessarily need to be rectangular, and may be any shape known in the art, as long as the void facilitates the wire-bond connection.

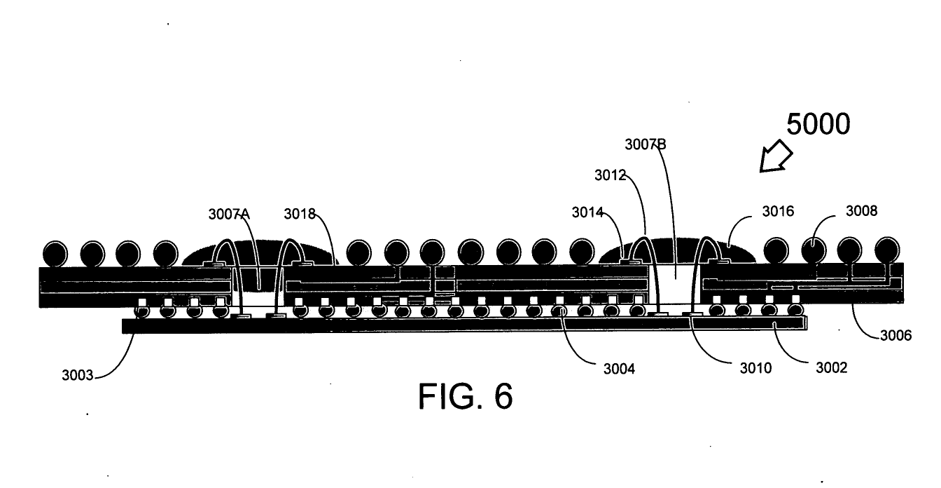

FIG. 6 is a cross-section view showing a single integrated-circuit hybrid flip chip and wire bond embodiment, configured with multiple voids to provide a greater number of power/ground pads and signal input/output pads on a single package. The embodiment illustrates the concept that multiple voids may be employed to facilitate wire-bond connections. It is understood that embodiments may contain more than two voids 3007 within a package substrate 3006, and indeed any number of voids 3007 may be contained within a single package substrate 3006.

This illustration may be thought of as a cross section of the embodiment shown in FIG. 5, viewed horizontally across integrated circuit 3002A, with voids 3007A-B.

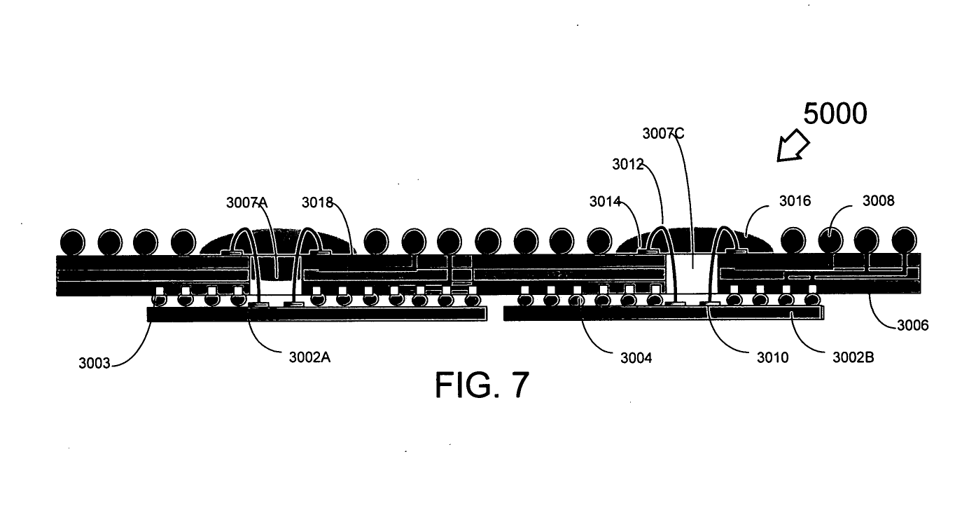

FIG. 7 is a cross-section view showing a multiple integrated-circuit hybrid flip chip and wire bond embodiment, configured with multiple voids to provide a greater number of power/ground pads and signal input/output pads on a single package. This embodiment shows depicts the concept that multiple integrated circuits may be placed beneath a single package substrate 3006. It is understood that embodiments may contain more than two integrated circuits 3002, and indeed any number of integrated circuits 3002 may be contained within a single package substrate 3006. The diagram may be thought of as a cross section of FIG. 5, viewed vertically across integrated circuits 3002A-B, with voids 3007A and 3007C.

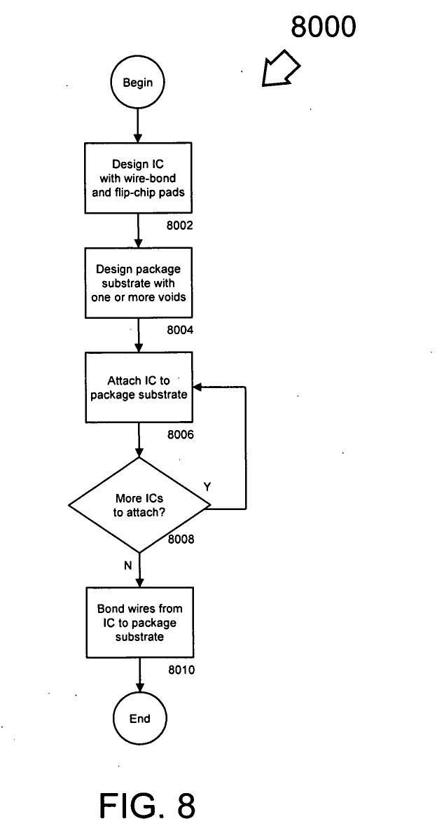

The process 8000 of constructing a hybrid flip chip and wire bond embodiment is depicted in FIG. 8, constructed and operative in accordance with embodiments of the present invention. Wire-bond pads and flip-chip pads are placed on the surface of one or more integrated circuits 3002, block 8002. A package substrate 3006 is designed with voids 3007 or areas to drill through the substrate material, block 8004. The integrated circuit is attached as a flip-chip to one side of the package substrate, block 8006. If there are more integrated circuits, as determined at block 8008, the attachments continue until all the integrated circuits 3002 are attached. The wires from wire-bond pads are bonded on the surface of chip to the other side of the substrate by through the voids, block 8010.

The previous description of the embodiments is provided to enable any person skilled in the art to practice the invention. The various modifications to these embodiments will be readily apparent to those skilled in the art, and the generic principles defined herein may be applied to other embodiments without the use of inventive faculty. Thus, the present invention is not intended to be limited to the embodiments shown herein, but is to be accorded the widest scope consistent with the principles and novel features disclosed herein.

What is claimed is:

1. A semiconductor connection package for an integrated circuit comprising:
a package substrate, the package substrate with at least one void, the package substrate having a top side and a bottom side;
a plurality of flip chip pads mounted on the bottom side of the package substrate, the plurality of flip chip pads configured to receive the integrated circuit;
a plurality of wire-bond pads mounted on the top side of the package substrate.

2. The package of claim 1 further comprising:
a ball grid array mounted on the top of the package substrate, and the package substrate is further configured to convey electrical signals to or from the plurality of flip chip pads and the wire bond pads to the ball grid array.

3. The package of claim 2 wherein the plurality of flip chip pads is configured to receive the integrated circuit via contacts made through conductive bonding members.

4. The package of claim 3 wherein the wire-bond pads are configured to be electrically connected to the integrated circuit via wires, the wires being configured to be connected to the integrated circuit through the void in the package substrate.

5. The package of claim 4 further comprising:
an encapsulation configured to non-conductively encapsulate the void in the package substrate.

6. The package of claim 5 wherein the package substrate has more than one void.

7. The package of claim 6 wherein the package substrate is configured to receive more than one integrated circuit.

8. The method of claim 7 wherein the encapsulation is epoxy, epoxy resin molding compound, or polyimide adhesive.

9. A method of connecting a semiconductor connection package to an integrated circuit, comprising:
mounting the integrated circuit to the bottom side of the package substrate, the package substrate having a plurality of flip chip pads mounted on a bottom side of the package substrate, the plurality of flip chip pads configured to receive the integrated circuit;
connecting pads on the integrated circuit to wire-bond pads mounted on a top side of the package substrate, the connection being accomplished with wires, the wires traveling through a void in the package substrate;
encapsulating the wires and the void in the package substrate with an electrically non-conductive material.

10. The method of claim 9 wherein the electrically non-conductive material is epoxy, epoxy resin molding compound, or polyimide adhesive.

11. The method of claim 10 wherein the flip chip pads are made of gold, copper, aluminum, or nickel.

12. The method of claim 11 wherein the package substrate is made of polyimide tape, FR-4, organic build-up, or ceramic.

13. An apparatus comprising:
an integrated circuit;
a package substrate, the package substrate with at least one void, the package substrate having a top side and a bottom side;
a plurality of flip chip pads mounted on the bottom side of the package substrate, the plurality of flip chip pads configured to receive the integrated circuit;
a plurality of wire-bond pads mounted on the top side of the package substrate.

14. The apparatus of claim 13 further comprising:
a ball grid array mounted on the top of the package substrate, and the package substrate is further configured to convey electrical signals to or from the plurality of flip chip pads and the wire bond pads to the ball grid array.

15. The apparatus of claim 14 wherein the plurality of flip chip pads is configured to receive the integrated circuit via contacts made through conductive bonding members.

16. The apparatus of claim 15 wherein the wire-bond pads are configured to be electrically connected to the integrated circuit via wires, the wires being configured to be connected to the integrated circuit through the void in the package substrate.

17. The apparatus of claim 16 further comprising:
an encapsulation configured to non-conductively encapsulate the void in the package substrate.

18. The apparatus of claim 17 wherein the package substrate has more than one void.

19. The apparatus of claim 18 wherein the package substrate is configured to receive more than one integrated circuit.

20. The apparatus of claim 19 wherein the encapsulation is epoxy, epoxy resin molding compound, or polyimide adhesive.
